(19) United States
(12) Patent Application Publication
(10) Pub. No.: US 2023/0284385 A1
(43) Pub. Date: Sep. 7, 2023

(54) SUBSTRATE

(71) Applicant: ROHM Co., LTD., Kyoto (JP)

(72) Inventor: Kenji HAMACHI, Kyoto (JP)

(21) Appl. No.: 18/178,001

(22) Filed: Mar. 3, 2023

(30) Foreign Application Priority Data
Mar. 7, 2022 (JP) 2022-034040

(51) Int. Cl. H05K 1/14

(52) U.S. Cl. CPC H05K 1/141; H05K 2201/041

(57) ABSTRACT

Provided is a substrate including a first substrate including a first surface, and a second substrate including a second surface with an area smaller than the first surface and including a third surface with an area smaller than the first surface, the third surface facing the second surface, as viewed in a thickness direction of the first substrate, in which the first substrate includes a first signal line and a second signal line formed on the first surface, and the second substrate includes a first conductive portion formed on the second surface and able to come into contact with the first signal line, a second conductive portion formed on the second surface and able to come into contact with the second signal line, a third conductive portion and a fourth conductive portion formed on the third surface, a first conduction portion, and a second conduction portion.

### CROSS REFERENCE TO RELATED APPLICATIONS

This application claims priority benefit of Japanese Patent Application No. JP 2022-034040 filed in the Japan Patent Office on Mar. 7, 2022. Each of the above-referenced applications is hereby incorporated herein by reference in its entirety.

### BACKGROUND

The technology disclosed in the present specification relates to a substrate.

A frequency characteristic measurement apparatus, such as a vector network analyzer, measures frequency characteristics of a device under test (DUT). In a typical measurement method in the related art, a Short-Open-Load-Thru (SOLT) calibration described in Kotomi Ichikawa and Yuichi Ichikawa, “Detailed explanation of S-parameters for high frequency circuit design,” fifth edition, CQ publishing Co., Ltd., Jan. 1, 2020, pp. 14 to 143 is carried out first on cable end surfaces. A short substrate prepared in place of the DUT, an open substrate prepared in place of the DUT, a substrate with a load prepared in place of the DUT, and a thru substrate in which the part provided with the DUT is removed from a sample substrate provided with the DUT are sequentially attached between cables, and the SOLT calibration is carried out. Subsequently, S-parameters of only the DUT are extracted from measurement results of S-parameters of the sample substrate provided with the DUT. As a result, pure frequency characteristics of the DUT can be obtained.

### SUMMARY

However, the typical measurement method in the related art requires four types of substrates for calibration. A large amount of cost is necessary for the substrates for calibration, and the calibration operation requires much time.

In addition, when a plurality of substrates are used in the frequency characteristic measurement of the DUT, the individual difference between the substrates leads to an error in the measurement.

A substrate disclosed in the present specification includes a first substrate including a first surface, and a second substrate including a second surface with an area smaller than the first surface and including a third surface with an area smaller than the first surface, the third surface facing the second surface, as viewed in a thickness direction of the first substrate. The first substrate includes a first signal line and a second signal line formed on the first surface. The second substrate includes a first conductive portion that is formed on the second surface and that is able to come into contact with the first signal line, a second conductive portion that is formed on the second surface and that is able to come into contact with the second signal line, a third conductive portion and a fourth conductive portion formed on the third surface, a first conduction portion that electrically connects the first conductive portion and the third conductive portion, and a second conduction portion that electrically connects the second conductive portion and the fourth conductive portion.

According to an embodiment of the technology disclosed in the present specification, the substrate that facilitates the improvement in the accuracy of the frequency characteristic measurement of the DUT can be provided.

### BRIEF DESCRIPTION OF THE DRAWINGS

FIG. 1 is a block diagram illustrating a schematic configuration of a frequency characteristic measurement apparatus according to an embodiment;

FIG. 2 is a schematic view illustrating a schematic structure of a first measurement substrate;

FIG. 3 is a schematic view illustrating a schematic structure of a second measurement substrate;

FIG. 4 is a flow chart illustrating an operation example of an extraction unit;

FIG. 5 schematically depicts S-parameters of a first fixture;

FIG. 6 schematically depicts S-parameters of a second fixture;

FIG. 7 schematically depicts S-parameters of the second measurement substrate;

FIG. 8 is a perspective view of a substrate;

FIG. 9 is a perspective view of a first substrate;

FIG. 10 depicts an example of a second substrate;

FIG. 11 depicts an example of mounting a DUT on the second substrate;

FIG. 12 depicts another example of mounting the DUT on the second substrate;

FIG. 13 depicts another example of the second substrate;

FIG. 14 depicts yet another example of the second substrate;

FIG. 15 depicts a modification of the second substrate;

FIG. 16 depicts a modification of the first substrate; and

FIG. 17 depicts another modification of the first substrate.

### DETAILED DESCRIPTION OF THE PREFERRED EMBODIMENT

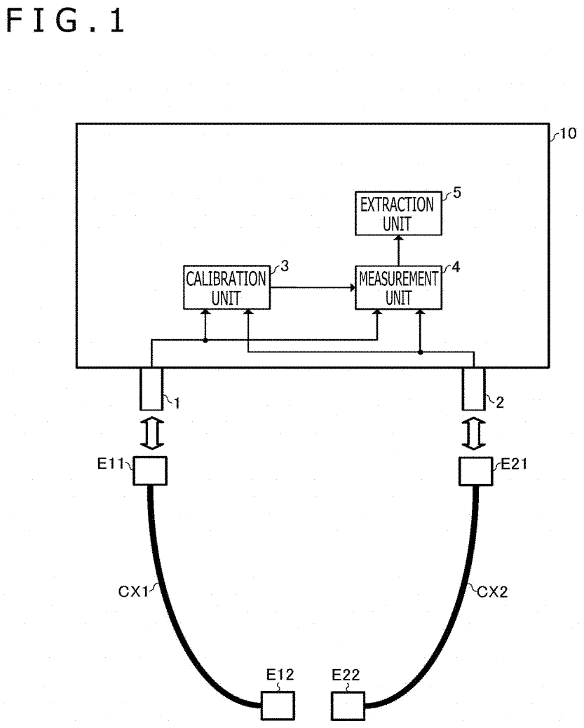

FIG. 1 is a block diagram illustrating a schematic configuration of a frequency characteristic measurement apparatus according to an embodiment. A frequency characteristic measurement apparatus 10 according to the embodiment illustrated in FIG. 1 (hereinafter, abbreviated as the “frequency characteristic measurement apparatus 10”) is a vector network analyzer.

The frequency characteristic measurement apparatus 10 includes a first port 1, a second port 2, a calibration unit 3, a measurement unit 4, and an extraction unit 5.

One end E11 of a first coaxial cable CX1 can be connected to the first port 1. One end E21 of a second coaxial cable CX2 can be connected to the second port 2.

The calibration unit 3 is configured to perform a SOLT calibration on cable end surfaces. Specifically, the one end E11 of the first coaxial cable CX1 is connected to the first port 1, and the one end E21 of the second coaxial cable CX2 is connected to the second port 2. The calibration unit 3 is configured to perform, in this state, a SOLT calibration on each of an end surface of another end E12 of the first coaxial cable CX1 and an end surface of another end E22 of the second coaxial cable CX2. The SOLT calibration on the cable end surfaces is a well-known technique disclosed in, for example, Kotomi Ichikawa and Yuichi Ichikawa, “Detailed explanation of S-parameters for high frequency circuit design,” fifth edition, CQ publishing Co., Ltd., Jan. 1, 2020, pp. 14 to 143, and the details will not be described here. The calibration unit 3 provides calibration results to the measurement unit 4.

The measurement unit 4 measures S-parameters. The measurement unit 4 functions as a first measurement unit and also functions as a second measurement unit.

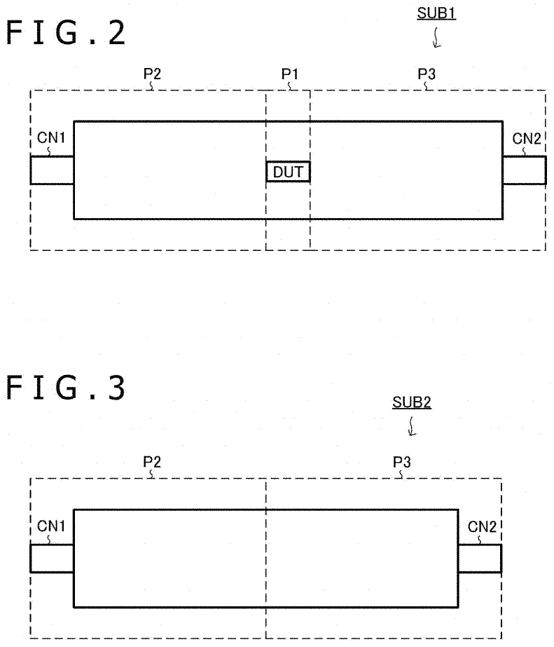

The first measurement unit is configured to measure S-parameters of a first measurement substrate SUB1 (see FIG. 2) provided with a DUT, after the SOLT calibration by the calibration unit 3. That is, the first measurement substrate SUB1 is connected to the frequency characteristic measurement apparatus 10 through the first coaxial cable CX1 and the second coaxial cable CX2 when the first measurement unit executes the measurement.

The second measurement unit is configured to measure S-parameters of a second measurement substrate SUB2 (see FIG. 3) in which the part provided with the DUT is removed from the first measurement substrate SUB1, after the SOLT calibration by the calibration unit 3. That is, the second measurement substrate SUB2 is connected to the frequency characteristic measurement apparatus 10 through the first coaxial cable CX1 and the second coaxial cable CX2 when the second measurement unit executes the measurement.

FIG. 2 is a schematic view illustrating a schematic structure of the first measurement substrate SUB1. FIG. 3 is a schematic view illustrating a schematic structure of the second measurement substrate SUB2. The first measurement substrate SUB1 includes a part P1 provided with a DUT, a first fixture P2, and a second fixture P3. The second measurement substrate SUB2 includes the first fixture P2 and the second fixture P3. In the second measurement substrate SUB2, the first fixture P2 and the second fixture P3 can be obtained by virtually dividing the second measurement substrate SUB2 into two pieces at the center.

The first fixture P2 includes a first connector CN1 that can be connected to the other end E12 of the first coaxial cable CX1. The first connector CN1 is provided at a left end of the first fixture P2. The second fixture P3 includes a second connector CN2 that can be connected to the other end E22 of the second coaxial cable CX2. The second connector CN2 is provided at a right end of the second fixture P3. Note that the first fixture P2 and the second fixture P3 have structures bilaterally symmetrical to each other. However, the first fixture P2 and the second fixture P3 may not have structures completely bilaterally symmetrical to each other, and there can be some manufacturing variations.

The extraction unit 5 is configured to perform a vector operation of the measurement results of the first measurement unit and the measurement results of the second measurement unit to extract the S-parameters of the DUT. The results of extraction performed by the extraction unit 5 may be stored in, for example, a portable storage medium that can be attached to and detached from the frequency characteristic measurement apparatus 10 or may be displayed on a display unit provided on the frequency characteristic measurement apparatus 10. The results of extraction may be output to the outside of the frequency characteristic measurement apparatus 10 through communication.

A computer program for processing the measurement results of the first measurement unit and the measurement results of the second measurement unit can be installed on a computer, such as a microcomputer, and the computer program can be executed to realize the extraction unit 5. Although the extraction unit 5 is built in the frequency characteristic measurement apparatus 10 in the present embodiment, a computer provided outside the frequency characteristic measurement apparatus 10 may function as the extraction unit 5.

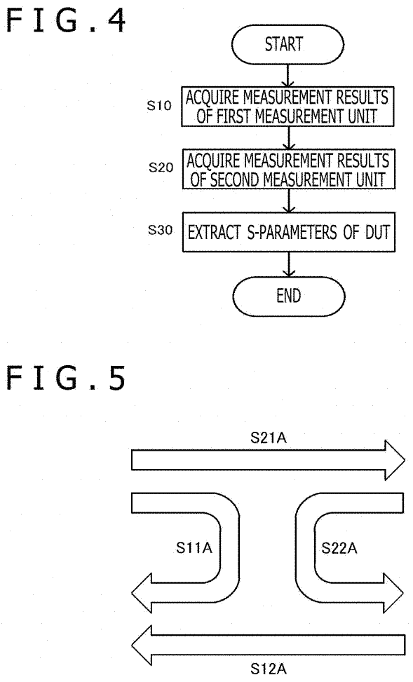

FIG. 4 is a flow chart illustrating an operation example of the extraction unit 5. The extraction unit 5 first acquires the measurement results of the first measurement unit (step S10). The extraction unit 5 then acquires the measurement results of the second measurement unit (step S20). Unlike in the present embodiment, step S20 may be executed first, and then step S10 may be executed. Step S10 and step S20 may be executed in parallel.

After acquiring the measurement results of the first measurement unit and the measurement results of the second measurement unit, the extraction unit 5 performs a vector operation of the measurement results of the first measurement unit and the measurement results of the second measurement unit to extract the S-parameters of the DUT (step S30) and ends the flow operation.

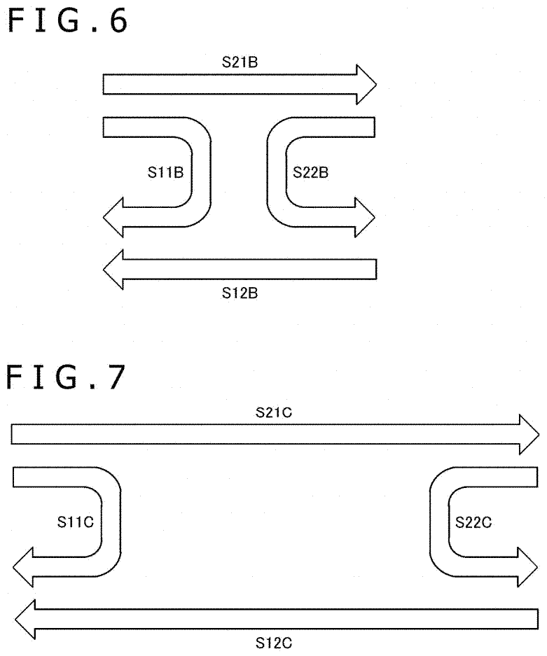

Details of the process of step S30 will next be described. FIG. 5 schematically depicts S-parameters of the first fixture P2. FIG. 6 schematically depicts S-parameters of the second fixture P3. FIG. 7 schematically depicts S-parameters of the second measurement substrate SUB2.

Because of the bilateral symmetry of the first fixture P2 and the second fixture P3, the extraction unit 5 sets S21A=S12B and S12A=S21B. The extraction unit 5 assumes that a reflection of each of the first fixture P2 and the second fixture P3 on an end surface of the second measurement substrate is equal to or smaller than a reflection on an end surface of the second measurement substrate SUB2 but does not assume that a reflection of each of the first fixture P2 and the second fixture P3 on a virtually divided surface is equal to or smaller than the reflection on the end surface of the second measurement substrate SUB2. Note that, when the extraction unit 5 “assumes that a reflection of each of the first fixture P2 and the second fixture P3 on an end surface of the second measurement substrate is equal to or smaller than a reflection on an end surface of the second measurement substrate SUB2,” it is sufficient if the extraction unit 5 can assume that the reflection of each of the first fixture P2 and the second fixture P3 on the end surface of the second measurement substrate is mostly or completely equal to or smaller than the reflection on the end surface of the second measurement substrate SUB2 in a frequency range of a measurement range. Hence, this does not exclude a case in which the reflection of each of the first fixture P2 and the second fixture P3 on the end surface of the second measurement substrate is partially higher than the reflection on the end surface of the second measurement substrate SUB2 in the frequency range of the measurement range. The extraction unit 5 obtains the S-parameters of the first fixture P2 and the S-parameters of the second fixture P3 from the measurement results of the second measurement unit. Specifically, the S-parameters of the first fixture P2 and the S-parameters of the second fixture P3 are as follows.

(1) The amplitude of S11A (S-parameter indicating the reflection of the first fixture P2 on the end surface of the second measurement substrate) is a single first fixed value throughout the entire frequency range of the measurement range.

(2) The phase of S11A is zero throughout the entire frequency range of the measurement range.

(3) S22A=(S22C-S11A)/S12C

(4) S21A=(1−S11B²×S21C)^{0.5}

(5) S12A=(1−S22A²×S12C)^{0.5}

(6) S11B=(S11C−S11A)/S21C

(7) The amplitude of S22B (S-parameter indicating the reflection of the second fixture P3 on the end surface of the second measurement substrate) is the single first fixed value throughout the entire frequency range of the measurement range.

(8) The phase of S22B is zero throughout the entire frequency range of the measurement range.

(9) S21B=S12A

(10) S12B=S21A

The extraction unit 5 performs a vector operation to subtract the S-parameters of the first fixture P2 and the S-parameters of the second fixture P3 from the measurement results of the first measurement unit and obtain the S-parameters of only the DUT.

In the measurement using the frequency characteristic measurement apparatus 10, a short substrate is not necessary in place of the DUT, an open substrate is not necessary in place of the DUT, and a substrate provided with a load is not necessary in place of the DUT. Thus, the frequency characteristic measurement apparatus 10 can conveniently measure the frequency characteristics of the DUT at low cost.

Assuming that the S-parameter S11A of the first fixture P2 is a value indicating a low reflection, an S-parameter S11 of the first measurement substrate SUB1 is substantially determined by the S-parameter S11B of the second fixture P3 when the DUT has high transmission characteristics. On the other hand, the S-parameter S11 of the first measurement substrate SUB1 is substantially determined by the S-parameter S11 of the DUT when the DUT has high reflection characteristics. Although two extreme cases including the case in which the DUT has high transmission characteristics and the case in which the DUT has high reflection characteristics have been described, the S-parameter S11 of the first measurement substrate SUB1 is also substantially determined by the S-parameter S11B of the second fixture P3 and the S-parameter S11 of the DUT in other cases.

Similarly, assuming that the S-parameter S22B of the second fixture P3 is a value indicating a low reflection, an S-parameter S22 of the first measurement substrate SUB1 is substantially determined by the S-parameter S22A of the first fixture P2 when the DUT has high transmission characteristics. On the other hand, the S-parameter S22 of the first measurement substrate SUB1 is substantially determined by the S-parameter S22 of the DUT when the DUT has high reflection characteristics. Although two extreme cases including the case in which the DUT has high transmission characteristics and the case in which the DUT has high reflection characteristics have been described, the S-parameter S22 of the first measurement substrate SUB1 is also substantially determined by the S-parameter S22A of the first fixture P2 and the S-parameter S22 of the DUT in other cases.

That is, it is reasonable for the extraction unit 5 to assume that the reflection of each of the first fixture P2 and the second fixture P3 on the end surface of the second measurement substrate is equal to or smaller than a predetermined level throughout the entire frequency range of the measurement range.

A measurement apparatus that, similarly to the frequency characteristic measurement apparatus 10, does not require a short substrate in place of the DUT, an open substrate in place of the DUT, and a substrate provided with a load in place of the DUT is disclosed in “Design criteria of automatic fixture removal (AFR) for asymmetric fixture de-embedding” (IEEE Conference Paper, p. 654 to p. 659, August 2014). However, it is presumed that the first fixture and the second fixture described in FIG. 2 of “Design criteria of automatic fixture removal (AFR) for asymmetric fixture de-embedding” (IEEE Conference Paper, p. 654-p. 659, August 2014) may not be virtually divided in an appropriate manner unless the distance between two end surfaces to be connected to the cables of the second measurement substrate SUB2 is equal to or more than twice the reciprocal of the lowest frequency of the measurement range. On the other hand, in the frequency characteristic measurement apparatus 10, the distance between two end surfaces to be connected to the cables of the second measurement substrate SUB2 does not have to be equal to or more than twice the reciprocal of the lowest frequency of the measurement range to obtain the S-parameters of (1) to (10). Hence, it is preferable that the distance between two end surfaces to be connected to the cables of the second measurement substrate SUB2 be less than twice the reciprocal of the lowest frequency of the measurement range from the viewpoint of reducing the size and cost of the second measurement substrate SUB2.

Although the extraction unit 5 assumes that the transmission characteristics of the first fixture P2 and the transmission characteristics of the second fixture P3 are symmetrical in the embodiment, the extraction unit 5 may not assume that the transmission characteristics of the first fixture P2 and the transmission characteristics of the second fixture P3 are symmetrical. Equation (9) described above is changed to Equation (9)′ described below, and Equation (10) described above is changed to Equation (10)′ described below, when the extraction unit 5 does not assume that the transmission characteristics of the first fixture P2 and the transmission characteristics of the second fixture P3 are symmetrical.

(9)′ S21B=(1−S11B²×S21C)^{0.5}

(10)′ S12B=(1−S22A²×S12C)^{0.5}

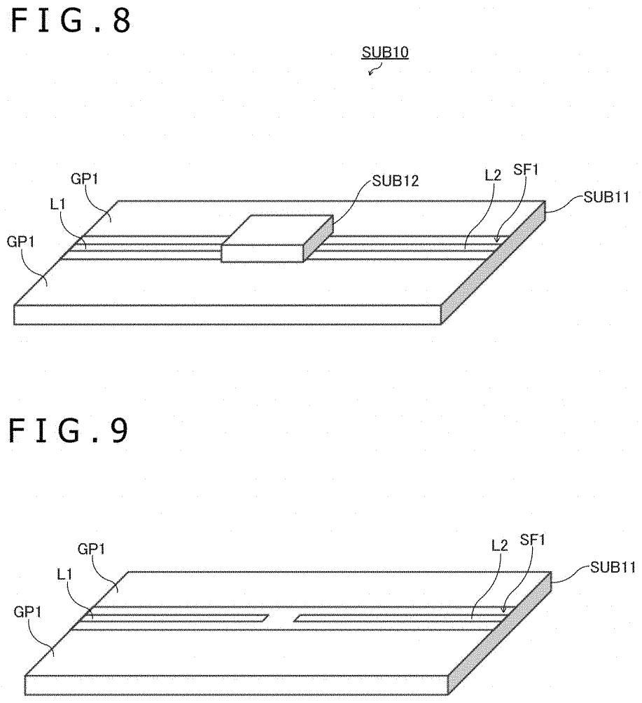

The individual difference between the first measurement substrate SUB1 and the second measurement substrate SUB2 leads to an error in the measurement. As such, to reduce the individual difference between the first measurement substrate SUB1 and the second measurement substrate SUB2, it is preferable that the first measurement substrate SUB1 and the second measurement substrate SUB2 be substrates in which the first connector CN1 and the second connector CN2 are attached to a substrate SUB10 illustrated in FIG. 8.

The substrate SUB10 includes a first substrate SUB11 and a second substrate SUB12 smaller than the first substrate SUB11.

The first substrate SUB11 and the second substrate SUB12 are substantially cuboid. More specifically, the first substrate SUB11 and the second substrate SUB12 are substantially flat.

A first signal line L1, a second signal line L2, and ground patterns GP1 are formed on an upper surface SF1 of the first substrate SUB11. The first signal line L1 and the second signal line L2 are placed between a pair of ground patterns GP1 in the width direction of the lines. That is, the first substrate SUB11 is a microstrip line substrate. The first signal line L1, the second signal line L2, and the ground patterns GP1 include, for example, metal thin films. The base of the first substrate SUB11 is an insulating material.

As illustrated in FIG. 9, the first signal line L1 and the second signal line L2 are separated from each other. That is, the first signal line L1 and the second signal line L2 are not electrically connected when the first substrate SUB11 is a single unit.

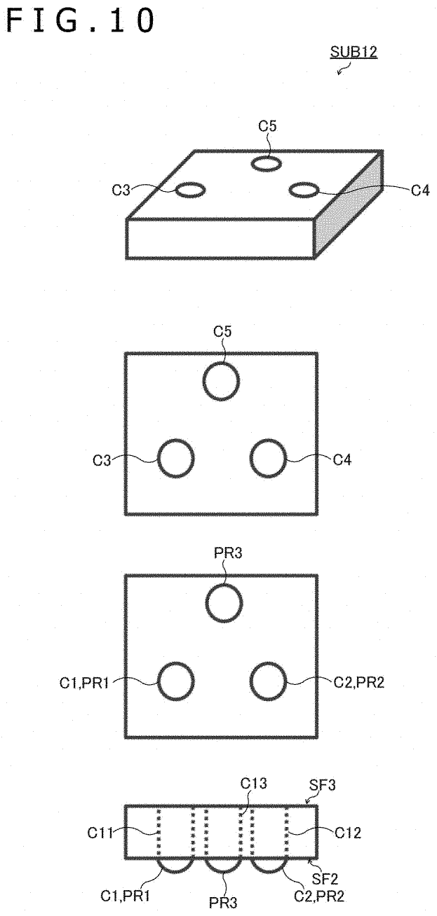

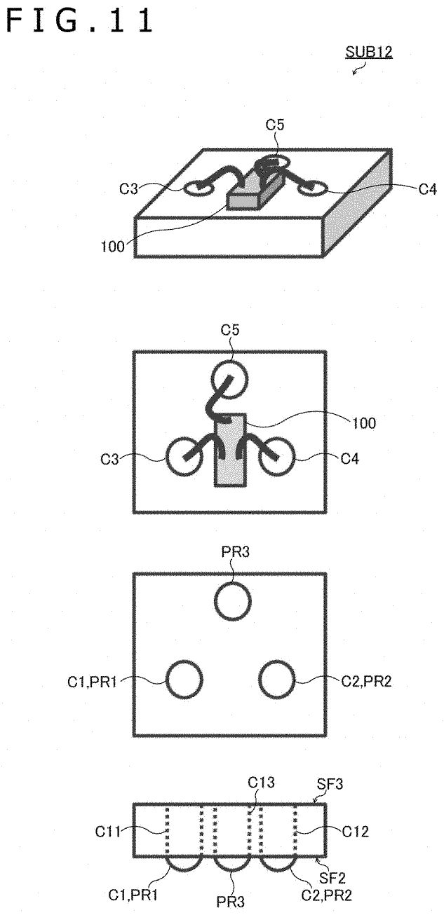

The second substrate SUB12 will next be described with reference to FIGS. 10 to 14. Each of FIGS. 10 to 14 depicts, from the top, a perspective view of the second substrate SUB12, a top view of the second substrate SUB12, a bottom view of the second substrate SUB12, and a front view of the second substrate SUB12.

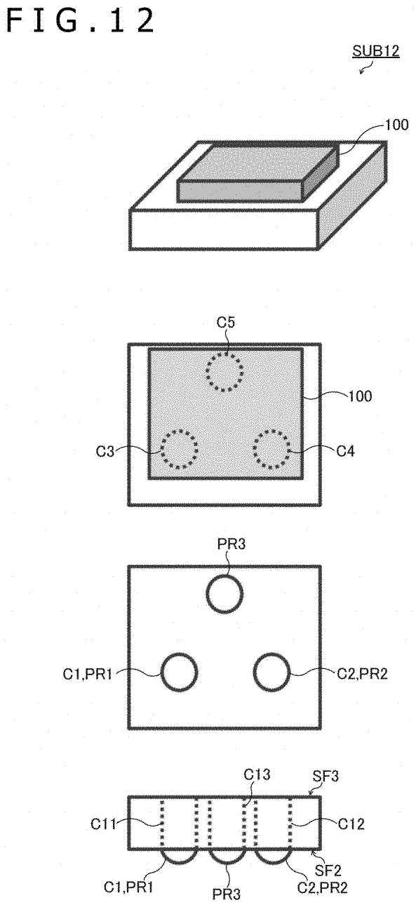

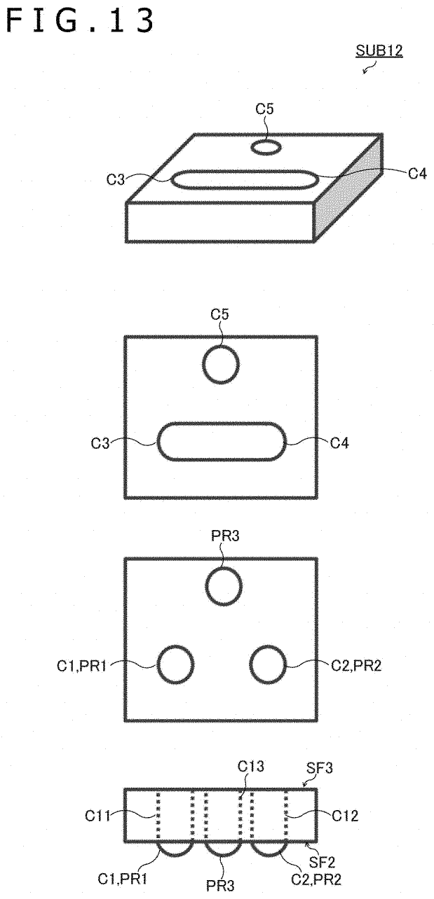

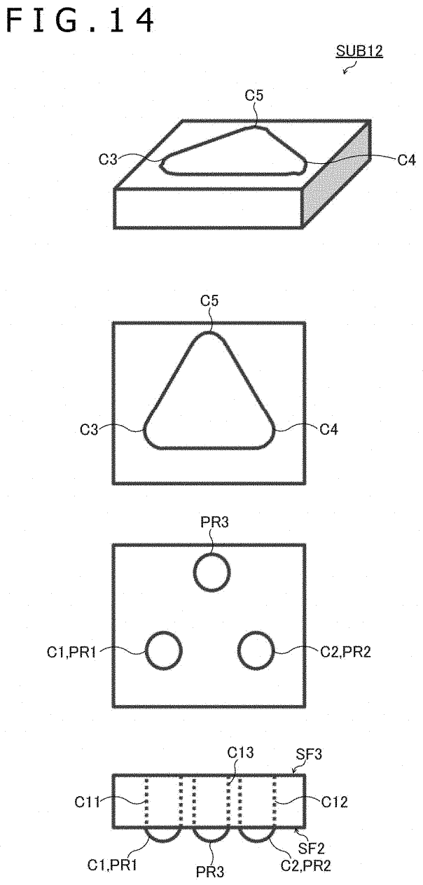

FIG. 10 depicts an example of the second substrate SUB12. FIG. 11 depicts an example of mounting a DUT 100 on the second substrate SUB12. FIG. 12 depicts another example of mounting the DUT 100 on the second substrate SUB12. FIG. 13 depicts another example of the second substrate SUB12. FIG. 14 depicts yet another example of the second substrate SUB12.

The second substrate SUB12 includes first to third projections PR1 to PR3 protruding from a lower surface SF2. The second substrate SUB12 is in contact with the first substrate SUB11 at three sections including the first to third projections PR1 to PR3. One plane is determined by three sections, and contact of the second substrate SUB12 and the first substrate SUB11 is stable. Here, the number of projections is not limited to three. For example, contact of the second substrate SUB12 and the first substrate SUB11 can be stabilized even if the number of projections is four or more as long as the variations in the amount of protrusion of the projections can be reduced.

The first to third projections PR1 to PR3 are substantially hemispherical. Accordingly, contact of each of the first to third projections PR1 to PR3 and the first substrate SUB11 is a point contact, and the contact of the second substrate SUB12 and the first substrate SUB11 is further stabilized.

Note that the first to third projections PR1 to PR3 may be formed into a shape other than the substantially hemispherical shape to make the contact of each of the first to third projections PR1 to PR3 and the first substrate SUB11 a point contact. For example, the shape of the first to third projections PR1 to PR3 may be a substantially conical shape.

The first projection PR1 is a first conductive portion C1 that can come into contact with the first signal line L1. The second projection PR2 is a second conductive portion C2 that can come into contact with the second signal line L2. The third projection PR3 is a conductive member that can come into contact with the ground patterns GP1.

The second substrate SUB12 includes a third conductive portion C3, a fourth conductive portion C4, and a fifth conductive portion C5 on an upper surface SF3 facing the lower surface SF2.

The second substrate SUB12 includes a first conduction portion C11 that electrically connects the first conductive portion C1 and the third conductive portion C3. The second substrate SUB12 includes a second conduction portion C12 that electrically connects the second conductive portion C2 and the fourth conductive portion C4. The second substrate SUB12 includes a third conduction portion C13 that electrically connects the third projection PR3 and the fifth conductive portion C5. The first to third conduction portions C11 to C13 are, for example, contact holes.

In the substrate SUB10, a plurality of types of second substrates SUB12 can be replaced to commonly use the first substrate SUB11 that makes up most of the substrate SUB10. Accordingly, the individual difference can be reduced in the substrate SUB10. The individual difference of the substrate SUB10 can be reduced to improve the accuracy of the frequency characteristic measurement of the DUT.

For example, the substrate SUB10 can be used as an “open substrate” when the second substrate SUB12 in which the third to fifth conductive portions C3 to C5 are separated from each other as illustrated in FIG. 10 is placed on the first substrate SUB11.

For example, the substrate SUB10 can be used as the “first measurement substrate SUB1” when the second substrate SUB12 in which the third to fifth conductive portions C3 to C5 are separated from each other and in which the DUT 100 is mounted as illustrated in FIG. 11 or FIG. 12 is placed on the first substrate SUB11.

Note that the DUT 100 is connected to the second substrate SUB12 by wire bonding in FIG. 11. The DUT 100 is connected to the second substrate SUB12 by soldering in FIG. 12.

For example, the substrate SUB10 can be used as the “second measurement substrate SUB2” when the second substrate SUB12 in which the third conductive portion C3 and the fourth conductive portion C4 are connected and in which the third conductive portion C3 and the fourth conductive portion C4 are separated from the fifth conductive portion C5 as illustrated in FIG. 13 is placed on the first substrate SUB11.

For example, the substrate SUB10 can be used as a “short substrate” when the second substrate SUB12 in which the third to fifth conductive portions C3 to C5 are connected as illustrated in FIG. 14 is placed on the first substrate SUB11.

In the second substrate SUB12 illustrated in FIG. 13, the DUT can be mounted across the third and fourth conductive portions C3 and C4 and the fifth conductive portion C5 to realize shunt-through.

In the second substrate SUB12 illustrated in FIG. 10, the DUT can also be mounted across the third conductive portion C3 and the fourth conductive portion C4 to realize series-through. In the case of the series-through, the fifth conductive portion C5 and the third conduction portion C13 may be excluded, and the third projection PR3 may be an insulating member.

In the substrate SUB10, the second substrate SUB12 may need to be pressed against the first substrate SUB11 from above to provide favorable electrical connection between the first substrate SUB11 and the second substrate SUB12.

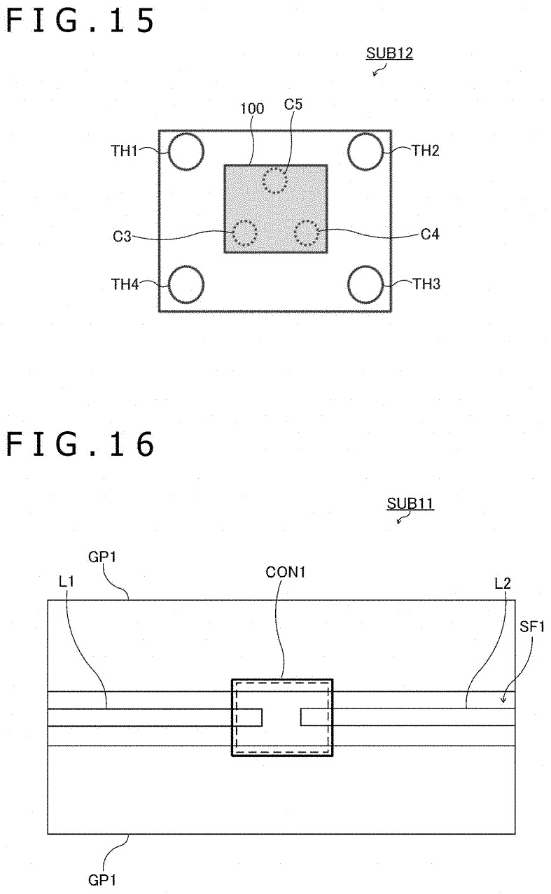

The method of pressing the second substrate SUB12 against the first substrate SUB11 from above is not particularly limited to any kind. For example, the first substrate SUB11 and the second substrate SUB12 may be wrapped in an insulating band. In addition, for example, a dedicated jig may be used to fix the second substrate SUB12 to the first substrate SUB11. In addition, for example, through holes TH1 to TH4 may be provided at four corners of the second substrate SUB12 as illustrated in FIG. 15, and four screw holes may be provided on the first substrate SUB11. The second substrate SUB12 may be screwed to the first substrate SUB11 by four bolts going through the through holes TH1 to TH4.

In the substrate SUB10, the second substrate SUB12 may need to be mounted on a predetermined position of the first substrate SUB11. That is, the position of the second substrate SUB12 with respect to the first substrate SUB11 may need to be adjusted in the substrate SUB10. It is preferable that the adjustment of the position of the second substrate SUB12 with respect to the first substrate SUB11 be easy.

FIG. 16 depicts a modification of the first substrate SUB11. The first substrate SUB11 illustrated in FIG. 16 includes a recessed portion CON1 recessed from the upper surface SF1. The first signal line L1 is formed on the upper surface SF1 and the recessed portion CON1. The second signal line L2 is formed on the upper surface SF1 and the recessed portion CON1. A dotted line in FIG. 16 illustrates an outer edge of the predetermined position. An outer edge of the recessed portion CON1 surrounds the outer edge of the predetermined position.

The adjustment of the position of the second substrate SUB12 with respect to the first substrate SUB11 is facilitated by use of the recessed portion CON1 as a guide of the second substrate SUB12.

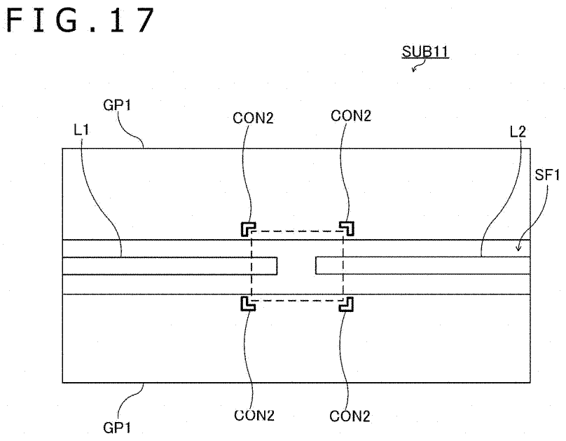

FIG. 17 depicts another modification of the first substrate SUB11. The first substrate SUB11 illustrated in FIG. 17 includes four projecting portions CON2 protruding from the upper surface SF1. A dotted line in FIG. 17 illustrates the outer edge of the predetermined position. The four projecting portions CON2 surround the outer edge of the predetermined position.

The adjustment of the position of the second substrate SUB12 with respect to the first substrate SUB11 is facilitated by use of the four projecting portions CON2 as a guide of the second substrate SUB12. Note that the number of projecting portions CON2 is not limited to four. For example, one annular projecting portion CON2 may be formed on the upper surface SF1 of the first substrate SUB11, or three or less or five or more projecting portions CON2 may be formed on the upper surface SF1 of the first substrate SUB11.

As described above, although the second substrate SUB12 is replaced in the substrate SUB10, the first substrate SUB11 is not replaced. Accordingly, the first connector CN1 and the second connector CN2 do not have to be repeatedly attached to and detached from the first substrate SUB11.

Hence, it is preferable to firmly fix the first connector CN1 and the second connector CN2 to the first substrate SUB11 by soldering, for example. This can prevent the connection of the first and second connectors CN1 and CN2 and the first substrate SUB11 from becoming unstable due to warpage of the first substrate SUB11 caused by residual stress generated upon attaching the first connector CN1 and the second connector CN2 to the first substrate SUB11 or due to warpage of the first substrate SUB11 caused by thermal stress in temperature characteristic evaluation.

The embodiment is illustrative in all aspects and should not be construed as restrictive. The technical scope of the technology disclosed in the present specification is indicated by the claims rather than the description of the embodiment, and it should be understood that all changes within the meaning and range of equivalents of the claims are included in the technical scope of the technology.

The substrate (SUB10) described above includes a first substrate including a first surface (SF1), and a second substrate including a second surface (SF2) with an area smaller than the first surface and including a third surface (SF3) with an area smaller than the first surface, the third surface facing the second surface, as viewed in a thickness direction of the first substrate, in which the first substrate includes a first signal line (L1) and a second signal line (L2) formed on the first surface, and the second substrate includes a first conductive portion (C1) that is formed on the second surface and that is able to come into contact with the first signal line, a second conductive portion (C2) that is formed on the second surface and that is able to come into contact with the second signal line, a third conductive portion (C3) and a fourth conductive portion (C4) formed on the third surface, a first conduction portion (C11) that electrically connects the first conductive portion and the third conductive portion, and a second conduction portion (C12) that electrically connects the second conductive portion and the fourth conductive portion (first configuration).

In the substrate with the first configuration, a plurality of types of second substrates can be replaced to commonly use the first substrate that makes up most of the substrate. Accordingly, the individual difference can be reduced in the substrate with the first configuration. The individual difference of the substrate can be reduced to improve the accuracy of the frequency characteristic measurement of the DUT.

In the substrate with the first configuration, the second substrate may include a first projection (PR1), a second projection (PR2), and a third projection (PR3) protruding from the second surface, the first projection may be the first conductive portion, and the second projection may be the second conductive portion (second configuration).

In the substrate with the second configuration, the second substrate is in contact with the first substrate at three sections including the first projection, the second projection, and the third projection. One plane is determined by three sections, and contact of the second substrate and the first substrate is stable.

In the substrate with the second configuration, the third projection may be a conductive member, and the second substrate may further include a fifth conductive portion (C5) formed on the third surface, and a third conduction portion (C13) that electrically connects the third projection and the fifth conductive portion (third configuration).

In the substrate with the third configuration, the part other than the first signal line and the second signal line formed on the first surface of the first substrate and the DUT can be electrically connected when the DUT is mounted on the second substrate.

In the substrate with the third configuration, the first substrate may further include a ground pattern (GP1) formed on the first surface, and the third projection may be able to come into contact with the ground pattern (fourth configuration).

In the substrate with the fourth configuration, a ground voltage can be supplied to the DUT when the DUT is mounted on the second substrate.

In the substrate with any one of the first to fourth configurations, the first substrate may include a recessed portion (CON1) recessed from the first surface, the first signal line may be formed on the first surface and the recessed portion, and the second signal line may be formed on the first surface and the recessed portion (fifth configuration).

In the substrate with the fifth configuration, the adjustment of the position of the second substrate is facilitated by use of the recessed portion as a guide of the second substrate.

In the substrate with any one of the first to fourth configurations, the first substrate may include a projecting portion (CON2) protruding from the first surface (sixth configuration).

In the substrate with the sixth configuration, the adjustment of the position of the second substrate is facilitated by use of the projecting portion as a guide of the second substrate.

What is claimed is:

1. A substrate comprising:
a first substrate including a first surface; and
a second substrate including a second surface with an area smaller than the first surface and including a third surface with an area smaller than the first surface, the third surface facing the second surface, as viewed in a thickness direction of the first substrate, wherein
the first substrate includes a first signal line and a second signal line formed on the first surface, and
the second substrate includes
a first conductive portion that is formed on the second surface and that is able to come into contact with the first signal line,
a second conductive portion that is formed on the second surface and that is able to come into contact with the second signal line,
a third conductive portion and a fourth conductive portion formed on the third surface,
a first conduction portion that electrically connects the first conductive portion and the third conductive portion, and
a second conduction portion that electrically connects the second conductive portion and the fourth conductive portion.

2. The substrate according to claim 1, wherein
the second substrate includes a first projection, a second projection, and a third projection protruding from the second surface,
the first projection is the first conductive portion, and
the second projection is the second conductive portion.

3. The substrate according to claim 2, wherein
the third projection is a conductive member, and
the second substrate further includes a fifth conductive portion formed on the third surface, and a third conduction portion that electrically connects the third projection and the fifth conductive portion.

4. The substrate according to claim 3, wherein
the first substrate further includes a ground pattern formed on the first surface, and
the third projection is able to come into contact with the ground pattern.

5. The substrate according to claim 1, wherein
the first substrate includes a recessed portion recessed from the first surface, and
the first signal line and the second signal line are formed on the first surface and the recessed portion.

6. The substrate according to claim 1, wherein
the first substrate includes a projecting portion protruding from the first surface.
